(19) United States
(12) Patent Application Publication
(10) Pub. No.: US 2018/0130663 A1
(43) Pub. Date: May 10, 2018

(54) SEMICONDUCTOR DEVICE MANUFACTURING METHOD

(71) Applicant: MIE FUJITSU SEMICONDUCTOR LIMITED, Kuwana-shi (JP)

(72) Inventor: Tetsuo Yoshimura, Kuwana (JP)

(73) Assignee: MIE FUJITSU SEMICONDUCTOR LIMITED, Kuwana-shi (JP)

(21) Appl. No.: 15/787,857

(22) Filed: Oct. 19, 2017

(30) Foreign Application Priority Data
Nov. 10, 2016 (JP) 2016-219738

(51) Int. Cl. H01L 21/285; H01L 27/06; H01L 49/02; H01L 29/872; H01L 29/06; H01L 21/822; H01L 29/66; H01L 21/265

(52) U.S. Cl. CPC H01L 21/28518; H01L 27/0676; H01L 28/24; H01L 29/872; H01L 29/665; H01L 21/822; H01L 29/66143; H01L 21/26513; H01L 29/0619

(57) ABSTRACT

A method of manufacturing a semiconductor device includes the following processes. A metal film forming process in which a metal film including cobalt is formed on a surface of silicon. A cap film forming process in which a cap film including titanium is formed on a surface of the metal film. A first thermal processing process in which a cobalt silicide is formed at a specific location of the semiconductor substrate by heating the semiconductor substrate at a first temperature. A second thermal processing process in which the semiconductor substrate is heated at a second temperature higher than the first temperature in nitrogen atmosphere. A removal process in which the cap film and unreacted cobalt are removed. A third thermal processing process in which the cobalt silicide is caused to phase transition by heating the semiconductor substrate at a third temperature higher than the second temperature.

### CROSS-REFERENCE TO RELATED APPLICATION

This application is based upon and claims the benefit of priority of the prior Japanese Patent Application No. 2016-219738, filed on Nov. 10, 2016, the entire contents of which are incorporated herein by reference.

### FIELD

The embodiments discussed herein are related to a manufacturing method of a semiconductor device.

### BACKGROUND

As technology that lowers resistance of silicon or polysilicon on a semiconductor substrate, a silicidation process is known that forms a silicide, which is a compound of silicon with a metal, on a surface of silicon or polysilicon. For example, the following technology is known in relation to silicidation processes.

Namely, a conventional silicidation process includes the following processes. A process that forms a cobalt layer on a MOS structure. A process that forms a titanium layer on the cobalt layer without exposing the cobalt layer to gas in which oxygen arises. A process that forms a titanium nitride layer on the titanium layer without exposing the titanium layer to gas in which oxygen arises. A process of forming silicified cobalt above a silicon source, a drain region, and a polysilicon gate region of a MOS structure by annealing the MOS structure at a first temperature. A process of removing unreacted cobalt, titanium, and titanium nitride from the MOS structure after the annealing described above. A subsequent process of converting the low temperature silicified cobalt formed at the first annealing temperature into high temperature silicified cobalt by annealing the MOS structure at a second temperature higher than the first temperature.

Further, another conventional silicidation process includes the following processes. A process of after forming a gate layer on an upper portion of a semiconductor substrate, forming a metal layer made from cobalt on an upper portion of a product obtained by patterning the gate layer. A process of forming a first capping layer made from metal on an upper portion of the metal layer. A process of forming cobalt monosilicide on an upper portion of the gate layer by heating the semiconductor substrate at a first temperature. A process of removing the unreacted metal layer and the first capping layer. A process of forming a second capping layer on an upper portion of the product. A process of changing the metal monosilicide into cobalt disilicide by heating the semiconductor substrate to a second temperature higher than the first temperature.

### Related Patent Documents

Japanese Patent Application Laid-Open (JP-A) No. H10-284732
JP-A No. 2008-22027

### Related Non-Patent Documents

IEDM1998. “High Thermal Stability and Low Junction Leakage Current of Ti Capped Co Salicide and its Feasibility for High Thermal Budget CMOS Devices”
IEDM1995. “Leakage Mechanism and Optimized Conditions of Co Salicide Process for Deep-Submicron CMOS Devices”

### SUMMARY

According to an aspect of the embodiments, a method of manufacturing a semiconductor device includes a metal film forming process, a cap film forming process, a first thermal processing process, a second thermal processing process, a removal process, and a third thermal processing process. In the metal film forming process, a metal film including cobalt is formed on a surface of silicon, polysilicon or a combination thereof, provided on a semiconductor substrate. In the cap film forming process, a cap film including titanium is formed on a surface of the metal film. In the first thermal processing process, a cobalt silicide is formed at a specific location of the semiconductor substrate by heating the semiconductor substrate at a first temperature in a nitrogen atmosphere and the titanium is nitrided. In the second thermal processing process, after the first thermal processing process, the semiconductor substrate is heated at a second temperature higher than the first temperature in nitrogen atmosphere. In the removal process, the cap film and unreacted cobalt are removed. In the third thermal processing process, after the removal process, the cobalt silicide is caused to phase transition by heating the semiconductor substrate at a third temperature higher than the second temperature.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1A is a plan view illustrating a configuration of a resistor element according to an exemplary embodiment of technology disclosed herein.

FIG. 1B is a cross-section sectioned along line 1B-1B in FIG. 1A.

FIG. 2A is a plan view illustrating a configuration of a Schottky barrier diode according to an exemplary embodiment of technology disclosed herein.

FIG. 2B is a cross-section sectioned along line 2B-2B of FIG. 2A.

FIG. 3A is a cross-section illustrating a manufacturing method of a semiconductor device according to an exemplary embodiment of technology disclosed herein.

FIG. 3B is a cross-section illustrating a manufacturing method of a semiconductor device according to an exemplary embodiment of technology disclosed herein.

FIG. 3C is a cross-section illustrating a manufacturing method of a semiconductor device according to an exemplary embodiment of technology disclosed herein.

FIG. 3D is a cross-section illustrating a manufacturing method of a semiconductor device according to an exemplary embodiment of technology disclosed herein.

FIG. 3E is a cross-section illustrating a manufacturing method of a semiconductor device according to an exemplary embodiment of technology disclosed herein.

FIG. 3F is a cross-section illustrating a manufacturing method of a semiconductor device according to an exemplary embodiment of technology disclosed herein.

FIG. 3G is a cross-section illustrating a manufacturing method of a semiconductor device according to an exemplary embodiment of technology disclosed herein.

FIG. 3H is a cross-section illustrating a manufacturing method of a semiconductor device according to an exemplary embodiment of technology disclosed herein.

FIG. 3I is a cross-section illustrating a manufacturing method of a semiconductor device according to an exemplary embodiment of technology disclosed herein.

FIG. 3J is a cross-section illustrating a manufacturing method of a semiconductor device according to an exemplary embodiment of technology disclosed herein

FIG. 4 is a process flowchart illustrating a flow of processing of a silicidation process according to an exemplary embodiment of technology disclosed herein.

FIG. 5 is a graph illustrating time-wise transitions in temperature of a semiconductor substrate when performing a first thermal processing and a second thermal processing of a silicidation process according to an exemplary embodiment of technology disclosed herein.

FIG. 6A is a graph illustrating time-wise transitions in temperature of a semiconductor substrate when performing thermal processing of a silicidation process according to a first comparative example.

FIG. 6B is a graph illustrating time-wise transitions in temperature of a semiconductor substrate when performing thermal processing of a silicidation process according to a second comparative example.

FIG. 7A is a cross-section illustrating states of respective layers surrounding a resistor body when a silicide layer has been formed on the surface of the resistor body using a silicidation process according to the first comparative example.

FIG. 7B is a cross-section illustrating a silicide layer formed on the surface of a resistor body using a silicidation process according to the first comparative example.

FIG. 8A is a cross-section illustrating states of respective layers in the vicinity of an n-well in a case in which a silicide layer has been formed on the surface of the n-well using a silicidation process according to the first comparative example.

FIG. 8B is a cross-section illustrating a silicide layer formed on the surface of an n-well using a silicidation process according to the first comparative example.

FIG. 9 is a process flowchart illustrating a flow of processing of a silicidation process according to an exemplary embodiment of technology disclosed herein.

FIG. 10 is a graph illustrating time-wise transitions in temperature of a semiconductor substrate when performing a first thermal processing and a second thermal processing of a silicidation process according to an exemplary embodiment of technology disclosed herein.

FIG. 11 is a graph illustrating magnitude and variation of sheet resistance values of resistor elements of respective samples according to comparative examples and examples.

FIG. 12 is a graph illustrating the magnitude of a forward voltage of a Schottky barrier diode of respective samples according to comparative examples and examples.

FIG. 13 is a graph illustrating weight percentages of proportions of titanium included in silicide layers (cobalt disilicide) of respective samples according to comparative examples and examples.

### DESCRIPTION OF EMBODIMENTS

A description of an exemplary embodiment of technology disclosed herein is given below, with reference to the drawings. Note that the same reference numerals are allocated to configuration element and portions that are the same or equivalent in each figure.

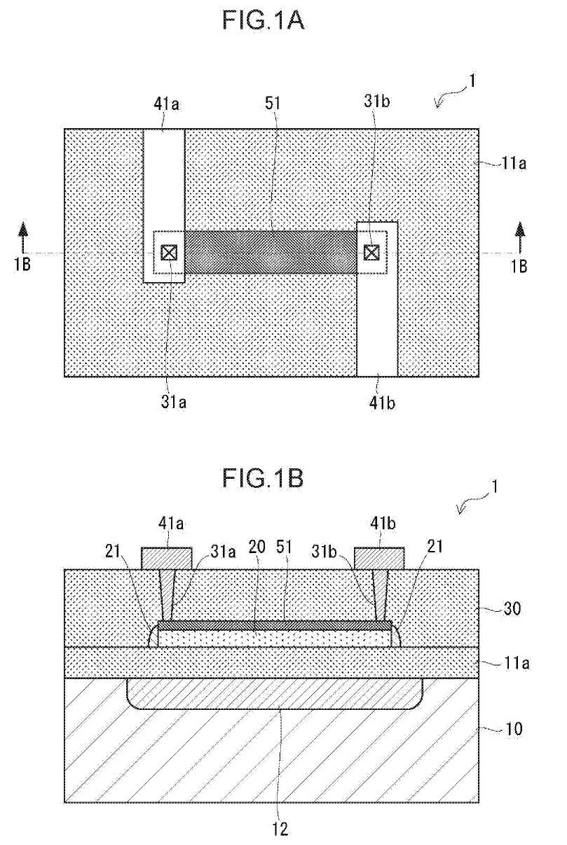

FIG. 1A is a plan view illustrating a configuration of a resistor element 1 that is an example of a semiconductor device manufactured using a manufacturing method according to an exemplary embodiment of technology disclosed herein. FIG. 1B is a cross-section sectioned along line 1B-1B in FIG. 1A. The resistor element 1 includes a resistor body 20 configured including polysilicon provided on a semiconductor substrate 10, and a silicide layer 51 formed on the surface of the resistor body 20.

The semiconductor substrate 10 is configured by monocrystalline silicon that has, for example, p-type electrical conductivity. A surface layer portion of the semiconductor substrate 10 is provided with a p-well 12 that has p-type electrical conductivity. Further, an insulating-separating film 11a configured by an insulator such as SiO₂ is provided to the surface layer portion of the semiconductor substrate 10 so as to cover the surface of the p-well 12. The resistor body 20 is provided above the insulating-separating film 11a, in a position superimposed on a formation region of the p-well 12. Side faces of the resistor body 20 are covered by side walls 21 configured by an insulator such as SiO₂.

The surface of the semiconductor substrate 10 is covered by an insulating film 30 configured by an insulator such as SiO₂. The resistor body 20, the silicide layer 51, and the side walls 21 are covered by the insulating film 30. Vias 31a and 31b that reach the silicide layer 51 are provided in the insulating film 30. The via 31a is connected to the silicide layer 51 at a position corresponding to one end portion of the resistor body 20, and the via 31b is connected to the silicide layer 51 at a position corresponding to another end portion of the resistor body 20. The surface of the insulating film 30 is provided with a resistor line 41a connected to the via 31a and a resistor line 41b connected to the via 31b.

Forming the silicide layer 51 on the surface of the resistor body 20 enables the resistance value between the resistor line 41a and the resistor line 41b to be made smaller, and enables a desired resistance value to be obtained in the resistor element 1. Note that in FIG. 1A, configuration elements other than the insulating-separating film 11a, the silicide layer 51, the vias 31a and 31b, and the resistor lines 41a and 41b are omitted from the diagram.

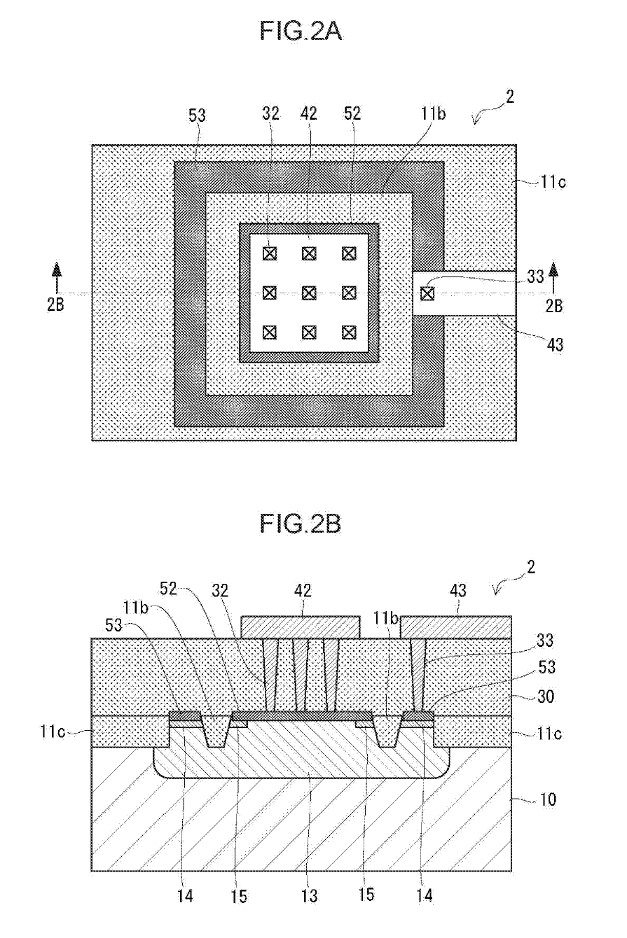

FIG. 2A is a plan view illustrating a configuration of a Schottky barrier diode (referred to as an SBD hereafter) 2, which is another example of a semiconductor device manufactured using the manufacturing method according to an exemplary embodiment of technology disclosed herein. FIG. 2B is a cross-section sectioned along line 2B-2B of FIG. 2A. The SBD 2 is configured including an n-well 13 having n-type electrical conductivity provided on the surface layer portion of the semiconductor substrate 10, and silicide layers 52 and 53 formed on the surface of the n-well. The SBD 2 is a diode that employs a Schottky barrier produced by a junction between the n-well 13 and the silicide layers 52, and the magnitude of a forward voltage Vf thereof has a characteristic of being smaller than that of a pn junction diode.

A surface layer portion of the n-well 13 is provided with an insulating-separating film 11b having a loop shape surrounding a central portion of the n-well 13. Further, the surface layer portion of the semiconductor substrate 10 is provided with an insulating-separating film 11c surrounding an outer periphery of the n-well 13. Further, a contact portion 14 is provided between the insulating-separating films 11b and 11c of the surface layer portion of the n-well 13. The contact portion 14 has n-type electrical conductivity and has a loop shape surrounding an outer periphery of the insulating-separating film 11b. Further, a guard ring 15 in contact with the insulating-separating film 11b at the inside of the insulating-separating film 11b is provided to the surface layer portion of the n-well 13. The guard ring 15 has p-type electrical conductivity and, similarly to the insulating-separating film 11b, has a loop shape surrounding a central portion of the n-well 13.

The silicide layer 52 is provided inside the insulating-separating film 11b and covers the surface of the n-well 13 at the central portion of the n-well 13. The silicide layer 52 functions as an anode electrode of the SBD 2. On the other hand, the silicide layer 53 covers the surface of the contact portion 14 provided at the outside of the insulating-separating film 11b. The silicide layer 53 functions as a cathode electrode of the SBD 2.

The surface of the semiconductor substrate 10 is covered by the insulating film 30. Further, a via 32 connected to the silicide layer 52 and a via 33 connected to the silicide layer 53 are provided inside the insulating film 30. An anode line 42 connected to the via 32 and a cathode line 43 connected to the via 33 are provided to the surface of the insulating film 30. Note that the resistor element 1 and the SBD 2 may be provided on the same semiconductor substrate 10.

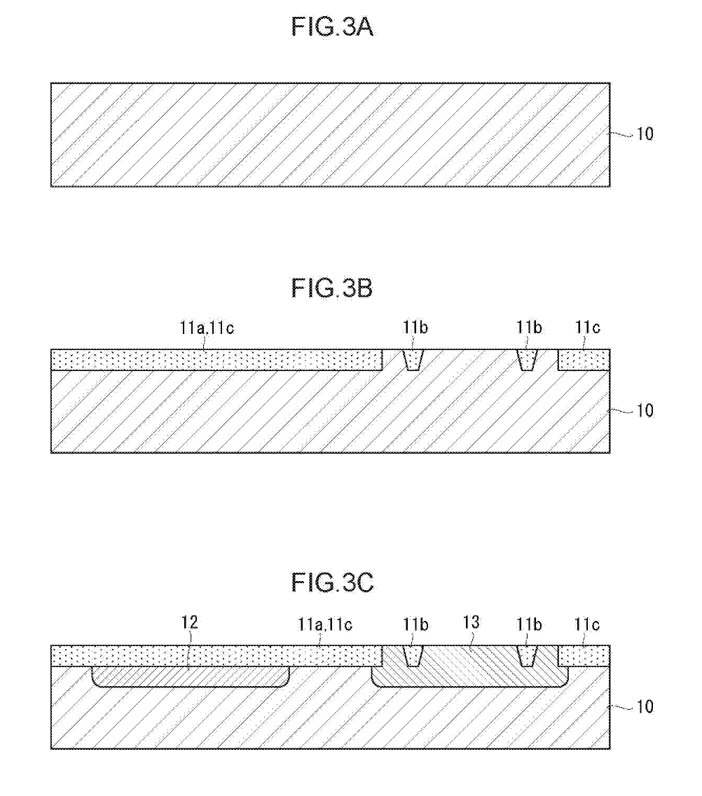

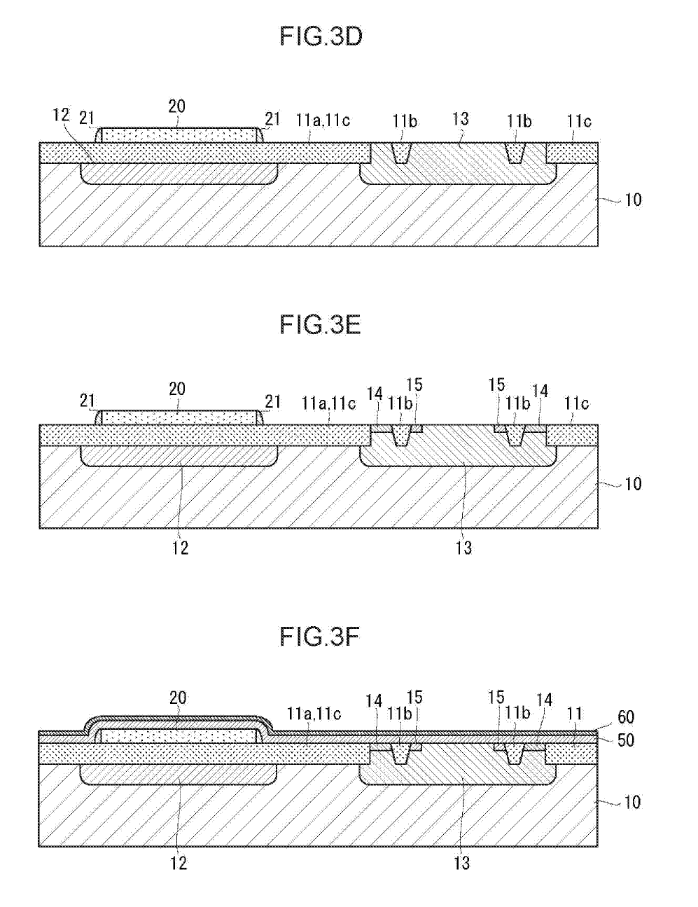

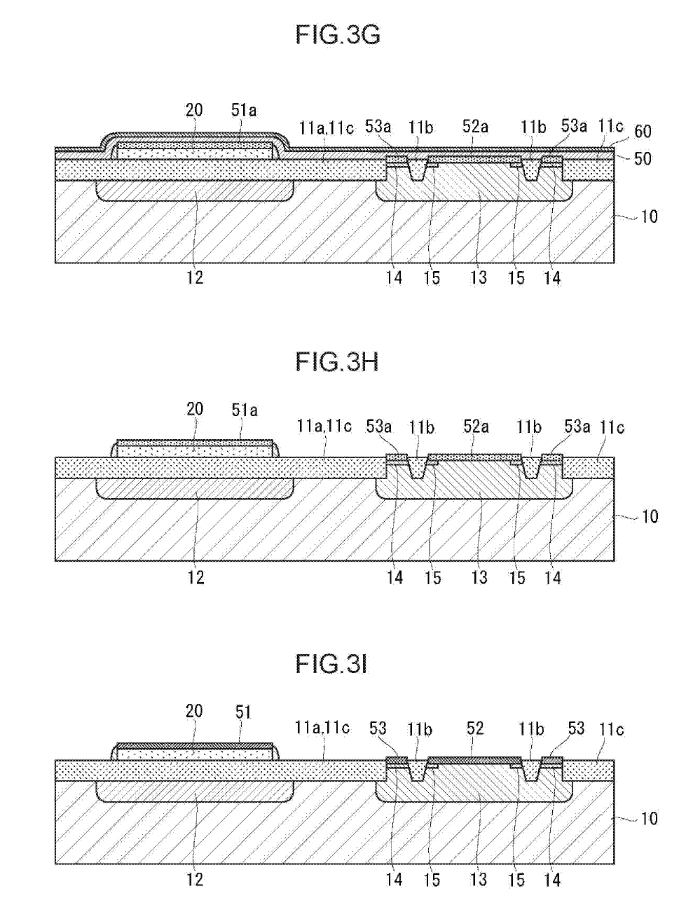

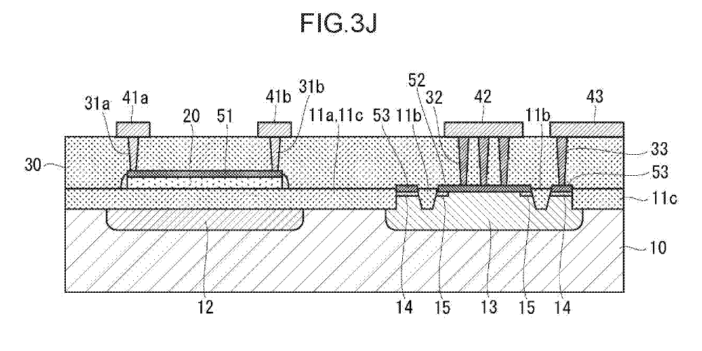

A manufacturing method of a semiconductor device according to an exemplary embodiment of technology disclosed herein that includes both the resistor element 1 and the SBD 2 is described below. Note that a DC-DC converter is given as an example of a circuit that includes both the resistor element 1 and the SBD 2. Technology disclosed herein is also applicable to cases in which at least one out of the resistor element 1 or the SBD 2 is included. FIG. 3A to FIG. 3J are cross-sections illustrating an example of a manufacturing method of a semiconductor device according to an exemplary embodiment of technology disclosed herein.

Firstly, the semiconductor substrate 10 configured by monocrystalline silicon having p-type electrical conductivity is prepared (FIG. 3A).

Next, for example, the insulating-separating films 11a, 11b, and 11c are configured by an insulator such as SiO₂ and are formed in specific regions of the surface layer portion of the semiconductor substrate 10 with depths of approximately 300 nm using a known shallow trench isolation (STI) method (FIG. 3B).

Next, an n-type impurity such as phosphorous is implanted into a formation region of the SBD 2 of the semiconductor substrate 10 using a known ion implantation method at a concentration of for example, 1×10¹³/cm³, thereby forming the n-well 13 in that region. Subsequently, a p-type impurity such as boron is implanted into a formation region of the resistor element 1 of the semiconductor substrate 10 using a known ion implantation method at a concentration of, for example 1×10¹³/cm³, thereby forming the p-well 12 in that region (FIG. 3C).

Next, a gate oxide film (not illustrated) is formed on the surface of the semiconductor substrate 10 using a known thermal oxidation method. Subsequently, polysilicon is formed on the gate oxide film using a known chemical vapor deposition (CVD) method. The polysilicon configures a gate of a transistor formed on the semiconductor substrate 10, not illustrated, and the resistor body 20 of the resistor element 1. Subsequently, the gate of the transistor (not illustrated) and the resistor body 20 are formed by patterning the polysilicon using known photolithographic technology and etching technology. The resistor body 20 is formed on the insulating-separating film 11a (FIG. 3D).

Next, an insulating film such as SiO₂ is formed on the surface of the semiconductor substrate 10 so as to cover the gate of the transistor (not illustrated) and the side face and upper face of the resistor body 20, and the side walls 21 that cover the gate of the transistor (not illustrated) and the side faces of the resistor body are formed by etching the insulating film using known anisotropic etching technology (FIG. 3D).

Next, an n-type impurity such as phosphorous is implanted at the outside of the insulating-separating film 11b of the surface of the n-well 13 using a known ion implantation method at a concentration of for example 1×10¹⁵/cm³, and the contact portion 14 is thereby formed in that location (FIG. 3E). Note that in the process of implanting the n-type impurity, a source and drain of an n-channel transistor, not illustrated, formed on the semiconductor substrate 10 are formed.

Next, a p-type impurity such as boron is implanted inside the insulating-separating film 11b of the surface of the n-well 13 using a known ion implantation method at a concentration of, for example 1×10¹⁵/cm³, and the guard ring 15 is thereby formed in that location (FIG. 3E). Note that the process of implanting the p-type impurity forms a source and drain of a p-channel transistor, not illustrated, formed on the semiconductor substrate 10.

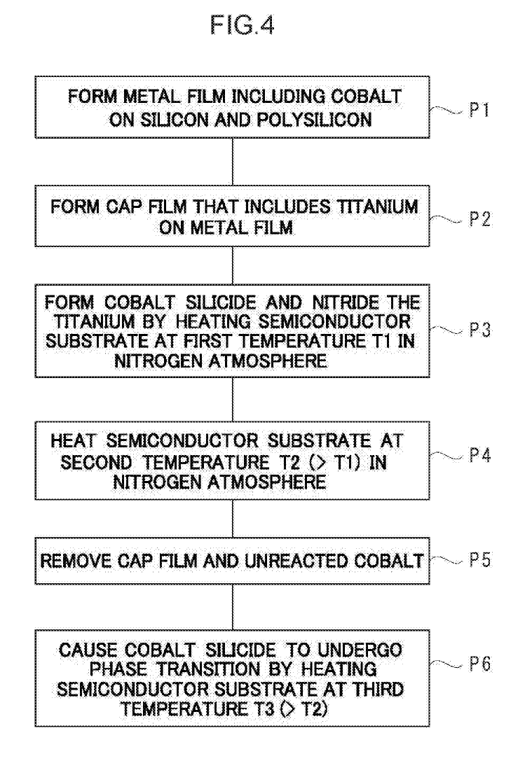

In the following processes, a silicide layer is formed on the surface of the resistor body 20 and the surface of the n-well 13 using a silicidation process. FIG. 4 is a process flowchart illustrating a flow of processes in a silicidation process according to a first exemplary embodiment of technology disclosed herein.

In a process P1, natural oxide films formed on the surfaces of the resistor body 20 and the n-well 13 are removed by wet etching or dry etching. Subsequently, a metal film 50 that includes cobalt as the main component and that has a thickness of approximately 7 nm is formed on the semiconductor substrate 10 using a known sputtering method so as to cover the surface of the resistor body 20 configured by the polysilicon and the surface of the n-well 13 configured by silicon (FIG. 3F).

In a process P2, a cap film 60 that includes titanium as the main component and that has a thickness of approximately 7 nm is formed on the metal film 50 using a known sputtering method (FIG. 3F). The cap film 60 has a role of preventing the cobalt of the metal film 50 from oxidizing.

In a process P3, the semiconductor substrate 10 is heated at a first temperature T1 in a nitrogen atmosphere. This heat processing is referred to as the first thermal processing hereafter. The first thermal processing is performed by rapid thermal annealing (RTA), which has a short heating time of from approximately several seconds to approximately several tens of seconds. The first thermal processing forms a silicide layer 51a that includes cobalt monosilicide (CoSi) as the main component on the surface of the resistor body 20 by reacting the polysilicon of the resistor body 20 with the cobalt of the metal film 50. Similarly, silicide layers 52a and 53a that include cobalt monosilicide (CoSi) as the main component are formed on the surface of the n-well 13 by reacting the silicon of the n-well 13 with the cobalt of the metal film 50 (FIG. 3G). Note that the silicide layer is not formed on the insulating-separating films 11a, 11b, and 11c. Further, the titanium of the cap film 60 is nitrided by the first thermal processing. The first temperature T1 is preferably temperature that suppresses the formation of titanium-cobalt alloy that inhibits the formation of the silicide layers 51a, 52a, and 53a (cobalt monosilicide); for example, from 480° C. to 510° C. is preferable.

In a process P4, the semiconductor substrate 10 is heated at a second temperature T2 higher than the first temperature T1 in a nitrogen atmosphere. This heat processing is referred to as the second thermal processing hereafter. Similarly to the first thermal processing, the second thermal processing is performed by RTA. The second thermal processing is performed in a state in which the metal film 50 and the cap film 60 remain as-is. Further, in the silicidation process according to the first exemplary embodiment, the second thermal processing is performed without lowering the temperature of the semiconductor substrate 10 after the first thermal processing. The second thermal processing promotes the formation of the silicide layers 51a, 52a, and 53a (cobalt monosilicide). Further, diffusion of the titanium diffused in the metal film 50 and in the titanium-cobalt alloy toward the silicide layers 51a, 52a, 53a (cobalt monosilicide) and toward the vicinity of the interface between the silicide layers 51a, 52a, and 53a and the resistor body 20 or the n-well 13 is also promoted. Diffusion of titanium lowers the barrier height of the Schottky barrier in the SBD 2 and lowers the forward voltage Vf of the SBD 2. On the other hand, since the titanium of the cap film 60 is nitrided by the first thermal processing, the formation of titanium-cobalt alloy that inhibits the formation of the silicide layers 51a, 52a, and 53a (cobalt monosilicide) is suppressed even when heated at the second temperature T2 higher than the first temperature T1 in the second thermal processing. The second temperature T2 is preferably a temperature that promotes the diffusion of the titanium toward the silicide layers 51a, 52a, and 53a (cobalt monosilicide) and toward the vicinity of the interface between the silicide layers 51a, 52a, and 53a and the resistor body 20 or the n-well 13. For example, the second temperature T2 is preferably from 540° C. to 580° C.

In a process P5, titanium-cobalt alloy, unreacted cobalt of the cobalt of the metal film 50 that did not react to form a silicide layer, and the cap film 60 are removed by chemical treatment (FIG. 3H).

In a process P6, the semiconductor substrate 10 is heated at a third temperature T3 higher than the second temperature T2 in a nitrogen atmosphere. This heat processing is referred to as a third thermal processing hereafter. Similarly to the first thermal processing and the second thermal processing, the third thermal processing is performed by RTA. The third thermal processing causes the cobalt monosilicide (CoSi) configuring the silicide layers 51a, 52a, and 53a to undergo a phase transition to cobalt disilicide (CoSi₂), which has lower resistance. Namely, the silicide layers 51, 52, and 53, which include cobalt disilicide (CoSi₂) as the main component, are formed (FIG. 3I). The third temperature T3 is, for example, approximately 700° C.

After the processes P1 to P6 of the silicidation process above have completed, the insulating film 30 configured by an insulator such as SiO₂ is formed on the surface of the semiconductor substrate 10 using a known CVD method (FIG. 3J). The silicide layer 51 formed on the surface of the resistor body 20 and the silicide layers 52 and 53 formed on the surface of the n-well 13 are covered by the insulating film 30. Subsequently, contact holes reaching the silicide layers 51, 52, and 53 are formed using known photolithography technology and known etching technology. Next, vias 31a, 31b, 32, and 33 are formed by filling these contact holes with an electrical conductor such as tungsten (FIG. 3J). Next, an electrically conductive film such as aluminum is formed on the surface of the insulating film 30 using a sputtering method, and the resistor lines 41a and 41b, the anode line 42, and the cathode line 43 are formed by patterning the electrically conductive film using known photolithography technology and known etching technology.

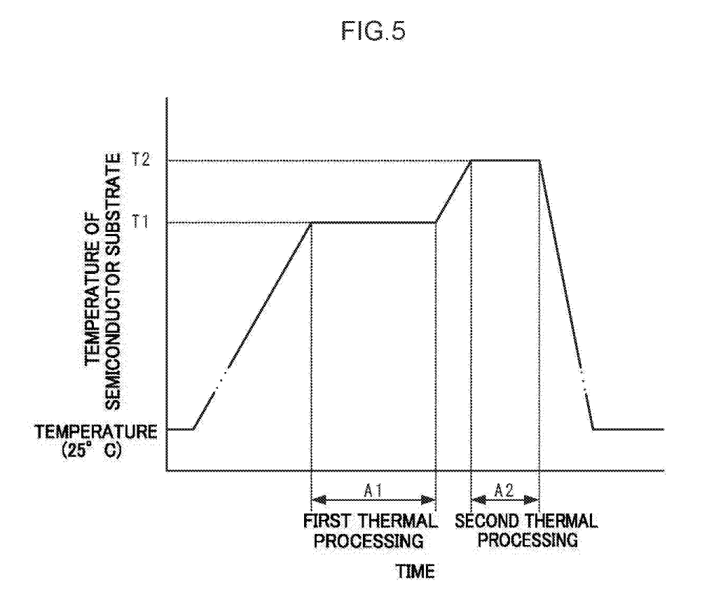

FIG. 5 is a graph illustrating time-wise transitions in the temperature of the semiconductor substrate 10 when the first thermal processing (process P3) and the second thermal processing (process P4) are performed in the silicidation process according to the first exemplary embodiment of technology disclosed herein described above. In the silicidation process according to the first exemplary embodiment, the semiconductor substrate 10 is heated from room temperature (25° C.) to the first temperature T1 and is kept in a heated state at the first temperature T1 until a first annealing time A1 elapses. Subsequently, the semiconductor substrate 10 is heated up to the second temperature T2 higher in temperature than the first temperature T1 and kept in a heated state at the second temperature T2 until a second annealing time A2 elapses. Subsequently, the semiconductor substrate 10 is cooled down to room temperature (25° C.). Thus, in the silicidation process according to the first exemplary embodiment, the heat processing to form the silicide layer that includes cobalt monosilicide (CoSi) as the main component on the surface of silicon or polysilicon is performed using two stages of heat processing that have different processing temperatures from each other.

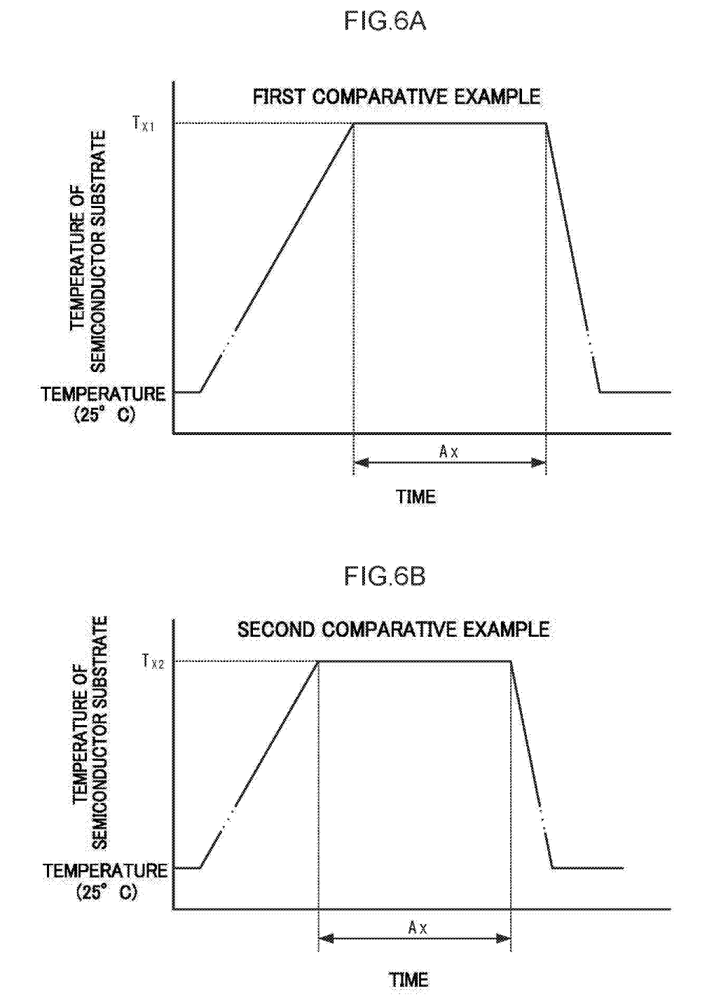

FIG. 6A is a graph illustrating time-wise transitions in the temperature of the semiconductor substrate 10 when performing heat processing to form a silicide layer that includes cobalt monosilicide (CoSi) as the main component on a surface of silicon or polysilicon using a silicidation process according to a first comparative example. In the silicidation process according to the first comparative example, a semiconductor substrate 10 is heated from room temperature (25° C.) up to a temperature T_{X1} and kept in a heated state at the temperature T_{X1} until an annealing time Ax has elapsed. Subsequently, the semiconductor substrate 10 is cooled down to room temperature (25° C.). Note that the temperature T_{X1} is equivalent to the second temperature T2 of the second thermal processing according to the exemplary embodiment of technology disclosed herein (T_{X1}=T2). Further, the annealing time Ax is equivalent to the total length of the annealing time A1 of first thermal processing and the annealing time A2 of the second thermal processing according to the exemplary embodiment of technology disclosed herein (Ax=A1+A2). Thus, in the silicidation process according to the first comparative example, the heat processing is performed by a one stage heat processing to form a silicide layer that includes cobalt monosilicide (CoSi) as the main component on the surface of silicon or polysilicon.

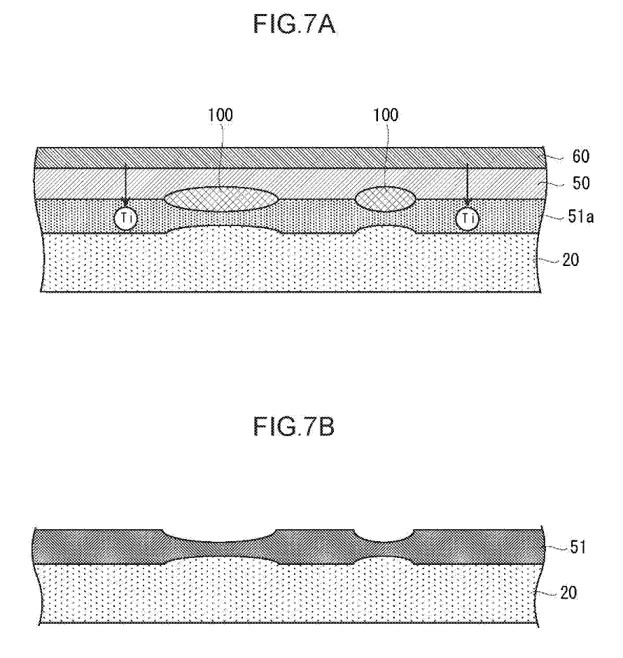

FIG. 7A is a cross-section illustrating the state of each layer surrounding the resistor body 20 when the silicidation process according to the first comparative example has been employed to form the silicide layer 51a that includes cobalt monosilicide (CoSi) as the main component on the surface of the resistor body 20 configuring the resistor element 1. FIG. 7B is a cross-section illustrating the state of each layer surrounding the resistor body 20 when the silicidation process according to the first comparative example has been employed to form the silicide layer 51 that includes cobalt disilicide (CoSi₂) as the main component on the surface of the resistor body 20 configuring the resistor element 1. In the silicidation process according to the first comparative example, heat processing is performed at the temperature T_{X1} (=T2), which is a comparatively high temperature. A portion of the titanium of the cap film 60 is accordingly diffused into the cobalt of the metal film 50, and another portion of the titanium is diffused into the cobalt monosilicide (CoSi) of the silicide layers 51a. A titanium-cobalt alloy 100 is thereby formed in the metal film 50 and the silicide layers 51a. The titanium-cobalt alloy 100 inhibits diffusion of cobalt atoms into the resistor body 20 (polysilicon). Accordingly, the thicknesses of the silicide layers 51a are made thinner at locations where the growth of the titanium-cobalt alloy 100 is more marked. The locations where the titanium-cobalt alloy 100 grows are random and the thicknesses of the silicide layers 51a therefore become non-uniform. As illustrated in FIG. 7B, this makes the thickness of the finally obtained silicide layer 51 that includes cobalt disilicide (CoSi₂) similarly non-uniform, and increases the variation in the resistance value of the resistor element 1.

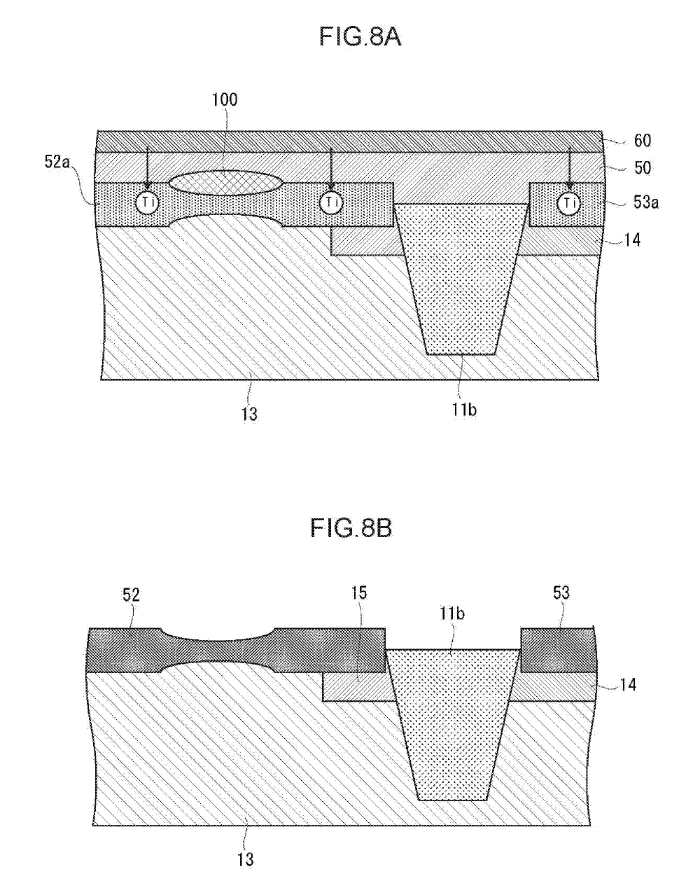

FIG. 8A is a cross-section illustrating the state of each layer in the vicinity of the n-well 13 when the silicidation process according to the first comparative example has been employed to form the silicide layers 52a and 53a that include cobalt monosilicide (CoSi) as the main component on the surface of the n-well 13 configuring the SBD 2. FIG. 8B is a cross-section illustrating the state of each layer surrounding the n-well 13 when the silicidation process according to the first comparative example has been employed to form the silicide layers 52 and 53 that include cobalt disilicide (CoSi₂) as the main component on the surface of the n-well 13 configuring the SBD 2. The silicidation process according to the first comparative example makes the thicknesses of the silicide layers 52a and 53a non-uniform due to the same mechanism as was described above. As illustrated in FIG. 8B, the thickness of the finally obtained silicide layers 52 and 53 that include cobalt disilicide (CoSi₂) accordingly becomes non-uniform.

FIG. 6B is a graph illustrating time-wise transitions in the temperature of a semiconductor substrate 10 when a silicidation process according to a second comparative example is used to perform heat processing to form a silicide layer that includes cobalt monosilicide (CoSi) as the main component on the surface of silicon or polysilicon. In the silicidation process according to the second comparative example, the semiconductor substrate 10 is heated from room temperature (25° C.) up to a temperature T_{X2} and is kept in a heated state at the temperature T_{X2} until an annealing time Ax has elapsed. Subsequently, the semiconductor substrate 10 is cooled down to room temperature (25° C.). Note that temperature T_{X2} is equivalent to the first temperature T1 of the first thermal processing according to the exemplary embodiment of technology disclosed herein (T_{X2}=T1<T2). Further, the annealing time Ax is equivalent to the total length of the annealing time A1 of the first thermal processing and the annealing time A2 of the second thermal processing according to the exemplary embodiment of technology disclosed herein (Ax=A1+A2). Thus, in the silicidation process according to the second comparative example, similarly to in the first comparative example, heat processing to form a silicide layer that includes cobalt monosilicide (CoSi) as the main component on the surface of silicon or polysilicon is performed by a one stage heat processing.

In the silicidation process according to the second comparative example, thermal processing to form the silicide layer that includes cobalt monosilicide (CoSi) as the main component is performed by one heat processing at the temperature T_{X2} (=T1<T2), which is a comparatively low temperature. This suppresses formation of titanium-cobalt alloy compared to cases in which the silicidation process according to the first comparative example is applied. However, since the processing temperature is a comparatively low temperature, growth of the cobalt monosilicide (CoSi) is not promoted and the thicknesses of the silicide layers 51a, 52a, and 53a are insufficient. This increases the resistance value of the resistor element 1 and further increases the variation in the resistance value. Further, since the processing temperature is a comparatively low temperature, diffusion of titanium toward the silicide layers 52a and 53a and toward the vicinity of the interface between the silicide layers 52a and 53a and the n-well 13 is not promoted. This increases the forward voltage Vf of the SBD 2 compared to cases in which the silicidation process according to the first comparative example is applied, without lowering the barrier height of the Schottky barrier of the SBD 2. The forward voltage Vf is preferably not increased, since having the magnitude of the forward voltage Vf be smaller than that of a pn junction diode is one of the characteristics of SBDs.

On the other hand, in the silicidation process according to the first exemplary embodiment of technology disclosed herein, the heat processing to form the silicide layer that includes cobalt monosilicide (CoSi) as the main component is performed by two stages of heat processing that have different processing temperatures from each other. The first thermal processing is performed using the first temperature T1, which is a comparatively low processing temperature. This enables the silicide layers 51a, 52a, and 53a to be formed while suppressing formation of titanium-cobalt alloy that inhibits formation of the silicide layers 51a, 52a, and 53a (cobalt monosilicide). Further, the titanium of the cap film 60 is nitrided by the first thermal processing.

Second thermal processing is performed using the second temperature T2, which is a comparatively high processing temperature. This promotes growth of the silicide layers 51a, 52a, and 53a (cobalt monosilicide). The titanium of the cap film 60 is nitrided by the first thermal processing and formation of titanium-cobalt alloy is suppressed. As the formation of the titanium-cobalt alloy is suppressed, growth of the silicide layers 51a, 52a, and 53a (cobalt monosilicide) is not easily inhibited. This enables the uniformity of the thicknesses of the silicide layers 51a, 52a, and 53a to be increased compared to cases in which the silicidation process according to the first comparative example is applied. Further, the thicknesses of the silicide layers 51a, 52a, 53a can be made thicker than in cases in which the silicidation process according to the second comparative example is applied. Namely, in the silicidation process according to the first exemplary embodiment of technology disclosed herein, the variation of the resistance value of the resistor element 1 can be made small compared to cases in which the silicidation process according to the first comparative example or the second comparative example is applied.

Further, the diffusion of titanium diffused in the metal film 50 and in titanium-cobalt alloy toward the silicide layers 51a, 52a, and 53 and toward the vicinity of the interface between the silicide layers 51a, 52a, 53a and the resistor body 20 or the n-well 13 is promoted by the second thermal processing. This enables the barrier height of the Schottky barrier of the SBD 2 to be made lower and enables the forward voltage Vf of the SBD 2 to be made smaller compared to cases in which the silicidation process according to the second comparative example is applied. Thus, in the silicidation process according to the first exemplary embodiment of technology disclosed herein, variation of the resistance value of the resistor element 1 can be made smaller while suppressing a rise in the forward voltage Vf of the SBD 2.

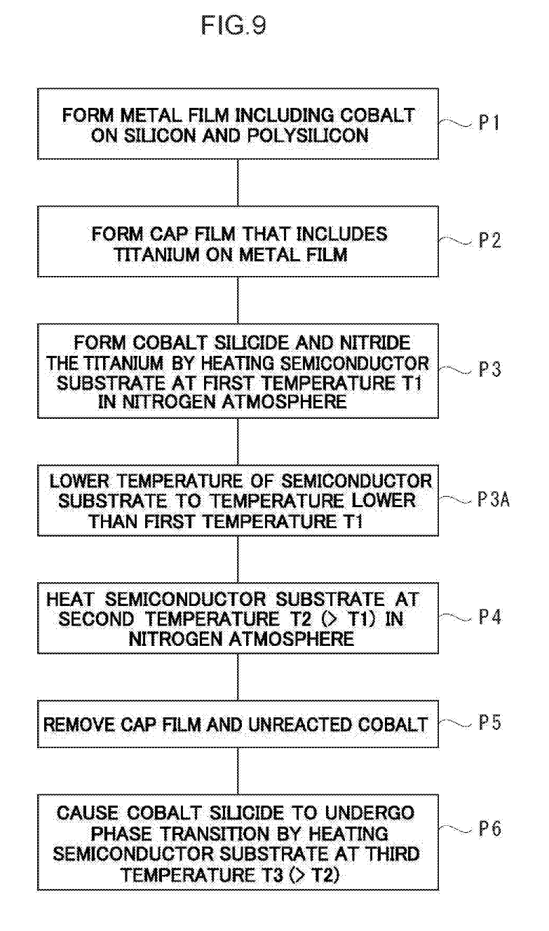

FIG. 9 is a process flowchart illustrating a flow of processing of the silicidation process according to a second exemplary embodiment of technology disclosed herein. The silicidation process according to the second exemplary embodiment is different from the silicidation process according to the first exemplary embodiment in that a process P3A is further included between the process P3 and the process P4. Namely, in the silicidation process according to the second exemplary embodiment, after having performed the first thermal processing in process P3, the temperature of the semiconductor substrate 10 in the process P3A is lowered to a temperature lower than the first temperature T1. The temperature of the semiconductor substrate 10 may, for example, be lowered to room temperature (25° C.) in process P3A. Subsequently, in process P4, the second thermal processing is performed and the temperature of the semiconductor substrate is increased to the second temperature T2 (>T1).

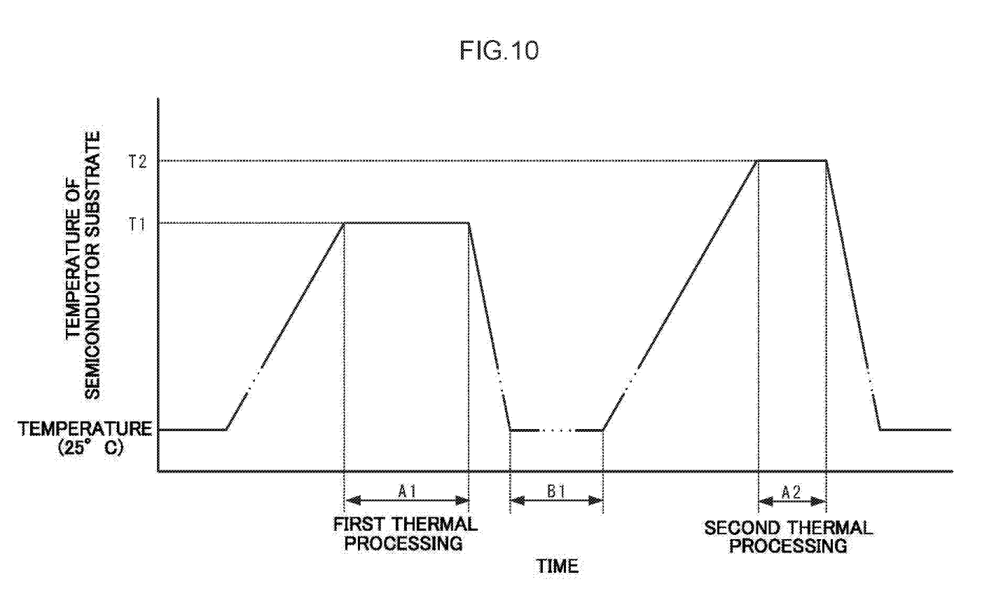

FIG. 10 is a graph illustrating time-wise transitions in the temperature of the semiconductor substrate 10 when the first thermal processing (process P3) and the second thermal processing (process P4) of the silicidation process are performed according to the second exemplary embodiment of technology disclosed herein described above. In the silicidation process according to the second exemplary embodiment, the semiconductor substrate 10 is heated from room temperature (25° C.) up to the first temperature T1 and is kept in a heated state at first temperature T1 until the first annealing time A1 elapses. Subsequently, the semiconductor substrate 10 is cooled down to room temperature (25° C.) and kept at room temperature (25° C.) until a waiting time B1 elapses. Note that the waiting time B1 is not a parameter that influences the characteristics of the resistor element 1 and the SBD 2 and is not particularly limited. However, an example of the waiting time B1 is from approximately 10 minutes to approximately 30 minutes. Subsequently, the semiconductor substrate 10 is heated from room temperature (25° C.) up to the second temperature T2 higher than the first temperature T1 and is kept in a heated state at the second temperature T2 until the second annealing time A2 elapses. Subsequently, the semiconductor substrate 10 is cooled down to room temperature (25° C.). Thus, in the silicidation process according to the second exemplary embodiment, the heat processing to form the silicide layer that includes cobalt monosilicide (CoSi) as the main component on the surface of silicon or polysilicon is performed using two stages of heat processing that have different processing temperatures from each other.

In the silicidation process according to the second exemplary embodiment of technology disclosed herein, similarly to the silicidation process according to the first exemplary embodiment, the variation of the resistance value of the resistor element 1 can be lowered while suppressing a rise in the forward voltage Vf of the SBD 2. Further, in the silicidation process according to the second exemplary embodiment, the advantageous effect of suppressing variation in the resistance value of the resistor element 1 can be further promoted. The mechanism thereof is hypothesized to be as follows.

Namely, in the silicidation process according to the first exemplary embodiment, the first thermal processing and the second thermal processing are continuous, and nuclei of titanium-cobalt alloy generated and grown in the first thermal processing continue to grow continuously in the second thermal processing. This makes locations where there is a large amount of localized growth of titanium-cobalt alloy liable to arise. Between the first thermal processing and the second thermal processing, nitriding of the titanium of the cap film 60 is furthered and there is an accompanying decrease in the supply of titanium, and growth of titanium-cobalt alloy is therefore retarded.

On the other hand, in the silicidation process according to the second exemplary embodiment, after completing the first thermal processing, there is a cooling period in which the temperature of the semiconductor substrate 10 up until the start of the second thermal processing is lowered to room temperature (25° C.). Growth of the titanium-cobalt alloy nuclei generated in the first thermal processing is accordingly temporarily stopped at the point in time when the first thermal processing completes. In the second thermal processing, titanium-cobalt alloy is also generated and grown in new locations that differ from the locations generated during the first thermal processing. Between the first thermal processing and the second thermal processing, the supply of titanium decreases as the nitriding of the titanium of the cap film 60 proceeds, and growth of titanium-cobalt alloy is accordingly retarded. Thus, in the silicidation process according to the second exemplary embodiment, the first thermal processing and the second thermal processing are discontinuous, making it difficult for continuous growth of titanium-cobalt alloy to occur, and making it difficult for locations where there is a large amount of localized growth of titanium-cobalt alloy to arise. Accordingly, it is conceivable that in comparison to the first exemplary embodiment, in the silicidation process according to the second exemplary embodiment, growth of cobalt monosilicide (Co—Si) is not easily inhibited, uniformity of the thickness of the silicide layer is improved, and the variation in the resistance value of the resistor element 1 is lowered.

### EXAMPLES

Sample resistor elements and SBDs were produced using the silicidation process according to the first exemplary embodiment and the silicidation process according to the second exemplary embodiment of technology disclosed herein described above, and the resistance values of resistor elements and the forward voltages Vf of the SBDs were evaluated. Further, for the sake of comparison, sample resistor elements and SBDs were produced using a silicidation process different from that of the exemplary embodiments of technology disclosed herein. The conditions of the heat processing to form the silicide layer that includes cobalt monosilicide (CoSi) as the main component on the surface of silicon or polysilicon were different for each sample. The heat processing conditions of each sample are listed in Table 1 below.

TABLE 1

| | Heat | | | | | | |
|---|---|---|---|---|---|---|---|
| | Processing | T1 | A1 | T2 | A2 | Tx | Ax |
| | Method | (° C.) | (sec) | (° C.) | (sec) | (° C.) | (sec) |
| Example 1 | Two stages, | 510 | 30 | 575 | 10 | — | — |
| | Continuous | | | | | | |
| Example 2 | Two stages, | 510 | 20 | 575 | 10 | — | — |
| | Continuous | | | | | | |
| Example 3 | Two stages, | 510 | 30 | 575 | 30 | — | — |
| | Separated | | | | | | |
| Example 4 | Two stages, | 510 | 30 | 575 | 10 | — | — |
| | Separated | | | | | | |
| Comparative | One stage | — | — | — | — | 575 | 60 |
| Example 1 | | | | | | | |
| Comparative | One stage | — | — | — | — | 575 | 30 |
| Example 2 | | | | | | | |
| Comparative | One stage | — | — | — | — | 510 | 30 |
| Example 3 | | | | | | | |

The samples according to Example 1 and Example 2 were produced using the silicidation process according to the first exemplary embodiment of technology disclosed herein with the first thermal processing and the second thermal processing performed continuously as illustrated in FIG. 5. The samples according to Example 3 and Example 4 were produced using the silicidation process according to the second exemplary embodiment of technology disclosed herein with the first thermal processing and the second thermal processing performed separated (namely, with a cooling period present between the first thermal processing and the second thermal processing) as illustrated in FIG. 10. In Table 1, T1 is the processing temperature of the first thermal processing, A1 is the annealing time of the first thermal processing, T2 is the processing temperature of the second thermal processing, and A2 is the annealing time of the second thermal processing.

The samples according to Comparative Example 1, Comparative Example 2 and Comparative Example 3 were formed by thermal processing in which a one stage heat processing was used to form the silicide layer that includes the cobalt monosilicide (CoSi). In Table 1, Tx is the processing temperature of the one stage heat processing and Ax is the annealing time of the one stage heat processing.

Note that the processing temperature and the annealing time for the phase transition from cobalt monosilicide (CoSi) to cobalt disilicide (CoSi₂) are the same for each sample: 700° C. and 30 seconds.

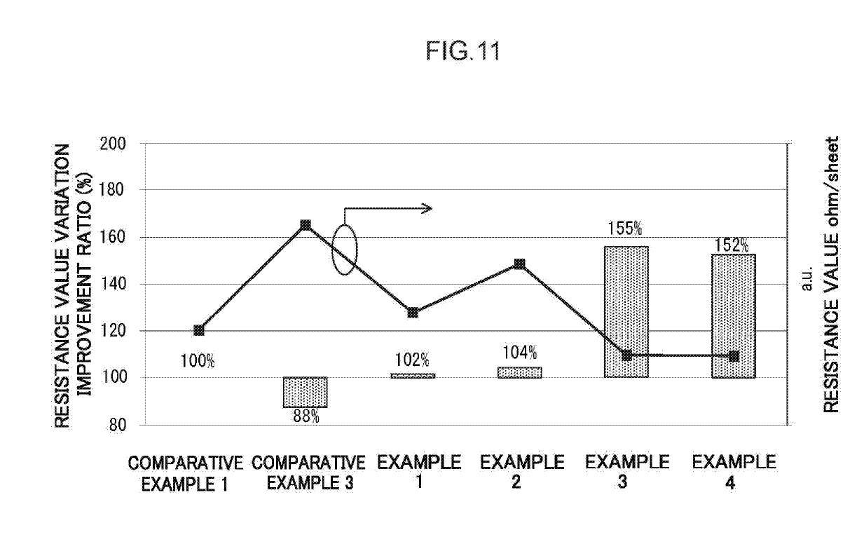

FIG. 11 is a graph illustrating the magnitude and variation of a sheet resistance value of the resistor element of each sample according to Comparative Example 1, Comparative Example 3, and Example 1 to Example 4. In FIG. 11, the resistance value variation improvement ratio indicated by a bar graph represents the ratio of the standard deviation of the sheet resistance value of the resistor element of each sample to the standard deviation of the sheet resistance value of the resistor element of the sample according to Comparative Example 1. Namely, the resistance value variation improvement ratio is defined such that the higher the value thereof the lower the variation of the resistance value of the resistor element. Further, when the resistance value variation improvement ratio exceeds 100%, this means that the variation of the resistance value of the resistor element of that sample is smaller than the sample according to Comparative Example 1. Further, in FIG. 11, the average value of the sheet resistance value of the resistor element of each sample is indicated by a line graph. Note that the number of samples employed in the computation of the standard deviation and the average value is 39 in each case.

As illustrated in FIG. 11, the variation of the resistance value of the sample according to Example 1 was improved by 2% with respect to the sample according to Comparative Example 1. The variation of the resistance value of the sample according to Example 2 was improved by 4% with respect to the sample according to Comparative Example 1. The variation of the resistance value of the sample according to Example 3 was improved by 55% with respect to the sample according to Comparative Example 1. The variation of the resistance value of the sample according to Example 4 was improved by 52% with respect to the sample according to Comparative Example 1. Thus, it was confirmed that the variation of the resistance value of the resistor element was smaller in the samples according to Example 1 to Example 4 produced using the silicidation process according to the first exemplary embodiment and the second exemplary embodiment of technology disclosed herein than in the sample according to Comparative Example 1. Further, there was a marked improvement effect on the variation of the resistance value in the sample according to Example 3 and Example 4. This is conceivably because in the silicidation process according to the second exemplary embodiment, localized growth of titanium-cobalt alloy is suppressed and the growth of cobalt monosilicide (Co—Si) is not as liable to be inhibited as in the first exemplary embodiment, as described above.

Further, as illustrated in FIG. 11, in the sample according to Comparative Example 3, the variation of the resistance value worsened by 12% with respect to the sample according to Comparative Example 1 and the magnitude of the sheet resistance value increased by approximately 40% with respect to the sample according to Comparative Example 1. This is conceivably because in Comparative Example 3, the processing temperature was low, growth of cobalt monosilicide (CoSi) was not promoted, and the thickness of the silicide layer was made thin. Namely, it is difficult to decrease the variation of the resistance value just by lowering the processing temperature to suppress the formation of titanium-cobalt alloy that inhibits growth of cobalt monosilicide (CoSi).

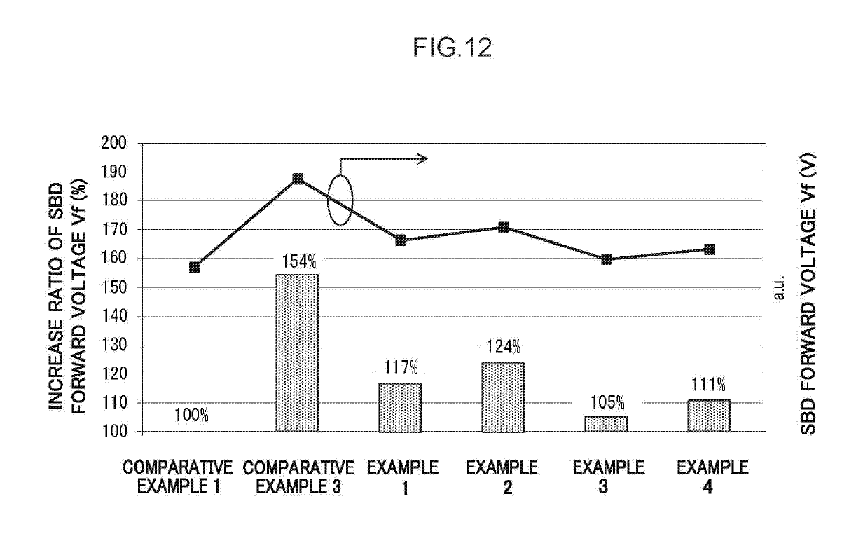

FIG. 12 is a graph illustrating the magnitude of the forward voltage Vf of the SBD of each sample according to Comparative Example 1, Comparative Example 3, and Example 1 to Example 4. In FIG. 12, the increased ratio of the forward voltage Vf of the SBD indicated by a bar graph represents the ratio of the average value of the forward voltage Vf of the SBD of each sample with respect to the forward voltage Vf of the SBD of the sample according to Comparative Example 1. Namely, when the increased ratio of the forward voltage Vf of the SBD exceeds 100%, this means that the magnitude of the forward voltage Vf of the SBD of that sample is greater than the sample according to Comparative Example 1. Further, in FIG. 12, the average value of the forward voltage Vf of the SBD of each sample is indicated by a line graph. Note that the number of samples employed in the computation of the average value of the forward voltage Vf of the SBD is 39 in each case.

As illustrated in FIG. 12, in the sample according to Comparative Example 3, the magnitude of the forward voltage Vf of the SBD has increased by more than 50% with respect to the sample according to Comparative Example 1. This is conceivably because in Comparative Example 3, the processing temperature is lower than that of Comparative Example 1, diffusion of titanium toward the silicide layer and toward the vicinity of the interface between the silicide layer and the silicon is not promoted, and the barrier height of the Schottky barrier of the SBD becomes higher than that of Comparative Example 1. An increase in the forward voltage Vf of the SBD is not preferable since the magnitude of the forward voltage Vf being lower than that of a pn junction diode is one of the characteristics of SBDs.

In the samples according to Example 1 to Example 4, the magnitude of the forward voltage Vf of the SBD has increased with respect to the sample according to Comparative Example 1, but the increase ratio is lower than that of the sample according to Comparative Example 3. This is conceivably because the diffusion of titanium was promoted by increasing the processing temperature T2 of the second thermal processing to a temperature higher than the processing temperature T1 of the first thermal processing such that the barrier height of the SBD was made lower than that of the sample according to Comparative Example 3.

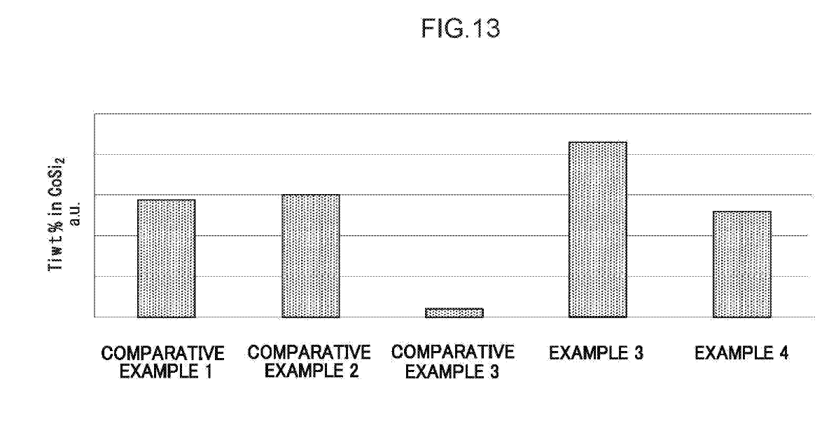

FIG. 13 is a graph illustrating weight percentages of the proportion of titanium included in the silicide layer (cobalt disilicide (CoSi₂)) of each sample according to Comparative Example 1 to Comparative Example 3 and Example 3 and Example 4. In Comparative Example 3, the processing temperature is lower than in Comparative Example 1 and Comparative Example 2, the diffusion of titanium toward the silicide layer is not promoted, and the proportion of titanium included in the silicide layer is less than in Comparative Example 1 and Comparative Example 2. On the other hand, in Example 3 and Example 4, the proportion of titanium included in the silicide layer is equivalent to that of Comparative Example 1 and Comparative Example 2. This is conceivably because in Example 3 and Example 4, although the processing temperature T1 of the first thermal processing is the same as the processing temperature Tx of Comparative Example 3, diffusion of titanium toward the silicide layer is promoted by the second thermal processing using the processing temperature T2 higher than the processing temperature T1.

An aspect of technology disclosed herein exhibits an advantageous effect of enabling variation in a resistance value of silicide to be suppressed.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A method of manufacturing a semiconductor device, the manufacturing method comprising:
a metal film forming process in which a metal film including cobalt is formed on a surface of silicon, polysilicon or a combination thereof, provided on a semiconductor substrate;
a cap film forming process in which a cap film including titanium is formed on a surface of the metal film;
a first thermal processing process in which a cobalt silicide is formed at a specific location of the semiconductor substrate by heating the semiconductor substrate at a first temperature in a nitrogen atmosphere and the titanium is nitrided;
a second thermal processing process in which, after the first thermal processing process, the semiconductor substrate is heated at a second temperature higher than the first temperature in nitrogen atmosphere;
a removal process in which the cap film and unreacted cobalt is removed; and
a third thermal processing process in which, after the removal process, the cobalt silicide is caused to phase transition by heating the semiconductor substrate at a third temperature higher than the second temperature.

2. The manufacturing method of claim 1, wherein the first temperature is a temperature that suppresses formation of a titanium-cobalt alloy.

3. The manufacturing method of claim 2, wherein the first temperature is from 480° C. to 510° C.

4. The manufacturing method of claim 1, wherein the second temperature is a temperature that promotes diffusion of the titanium into the cobalt silicide.

5. The manufacturing method of claim 4, wherein the second temperature is from 540° C. to 580° C.

6. The manufacturing method of claim 1, wherein a transition to the second thermal processing process is made after the first thermal processing process without lowing the temperature of the semiconductor substrate.

7. The manufacturing method of claim 1, wherein, after the first thermal processing process, the temperature of the semiconductor substrate is lowered to a temperature lower than the first temperature and then transition is made to the second thermal processing process.

8. The manufacturing method of claim 1, wherein, after the first thermal processing process, the temperature of the semiconductor substrate is lowered to room temperature and then transition is made to the second thermal processing process.

9. The manufacturing method of claim 1, wherein a Schottky barrier diode is formed so as to include the silicon and the cobalt silicide formed on a surface of the silicon.

10. The manufacturing method of claim 1, wherein a resistor element is formed so as to include the polysilicon and the cobalt silicide formed on a surface of the polysilicon is formed.
